(19) United States
(12) Patent Application Publication
(10) Pub. No.: US 2010/0027340 A1
(43) Pub. Date: Feb. 4, 2010

(54) PATTERN DEPENDENT STRING RESISTANCE COMPENSATION

(76) Inventors: Ercole Rosario Di Iorio, Scurcola Marsicana (IT); Pasquale Conenna, Bari (IT)

Correspondence Address: COOL PATENT, P.C.;c/o CPA Global, P.O. BOX 52050, MINNEAPOLIS, MN, 55402, US

(21) Appl. No.: 12/183,544

(22) Filed: Jul. 31, 2008

(51) Int. Cl. G11C 16/04; G11C 16/06; G11C 7/00

(52) U.S. Cl. 365/185.17; 365/185.25; 365/185.18; 365/203

(57) ABSTRACT

Pattern dependent string resistance compensation of a memory device is generally described. In one example, an electronic device includes a first string of memory cells and a first bit line coupled with the first string of memory cells wherein a memory cell of the first string of memory cells is read, in part, by pre-charging the first bit line through the first string of memory cells to compensate for resistance of unselected cells in the first string of memory cells.

### TECHNICAL FIELD

Embodiments of the present invention are generally directed to the field of memory and, more particularly, to sensing schemes and associated circuitry of memory devices.

### BACKGROUND

Generally, sensing approaches for memory devices may be partially affected by string current dependency factors other than the threshold voltage (Vt) and transconductance (gm) of a selected cell. For example, a sensing scheme may be affected by pattern dependent string resistance. String resistance dependency on a programmed pattern, which may be unknown, may slow down a bit line discharge during developing time with the effect of an apparently higher sensed threshold voltage (Vt) of a selected cell.

### BRIEF DESCRIPTION OF THE DRAWINGS

Embodiments disclosed herein are illustrated by way of example, and not by way of limitation, in the figures of the accompanying drawings in which like reference numerals refer to similar elements and in which:

FIG. 1 is a circuit diagram of a memory device for string resistance compensation, according to but one embodiment;

FIG. 2 is a schematic of a first sequence to provide string resistance compensation in a memory device, according to but one embodiment;

FIG. 3 is a schematic of a second sequence to provide string resistance compensation in a memory device, according to but one embodiment;

FIG. 4 is a flow diagram of a method to provide string resistance compensation in a memory device, according to but one embodiment; and

FIG. 5 is a diagram of an example system in which a memory device as described herein may be used, according to but one embodiment.

For simplicity and/or clarity of illustration, elements illustrated in the figures have not necessarily been drawn to scale. For example, the dimensions of some of the elements may be exaggerated relative to other elements for clarity. Further, if considered appropriate, reference numerals have been repeated among the figures to indicate corresponding and/or analogous elements.

### DETAILED DESCRIPTION

Embodiments of pattern dependent string resistance compensation are described herein. In the following description, numerous specific details are set forth to provide a thorough understanding of embodiments disclosed herein. One skilled in the relevant art will recognize, however, that the embodiments disclosed herein can be practiced without one or more of the specific details, or with other methods, components, materials, and so forth. In other instances, well-known structures, materials, or operations are not shown or described in detail to avoid obscuring aspects of the specification.

Reference throughout the specification to “one embodiment” or “an embodiment” means that a particular feature, structure or characteristic described in connection with the embodiment is included in at least one embodiment. Thus, appearances of the phrases “in one embodiment” or “in an embodiment” in various places throughout the specification are not necessarily referring to the same embodiment. Furthermore, the particular features, structures or characteristics may be combined in any suitable manner in one or more embodiments.

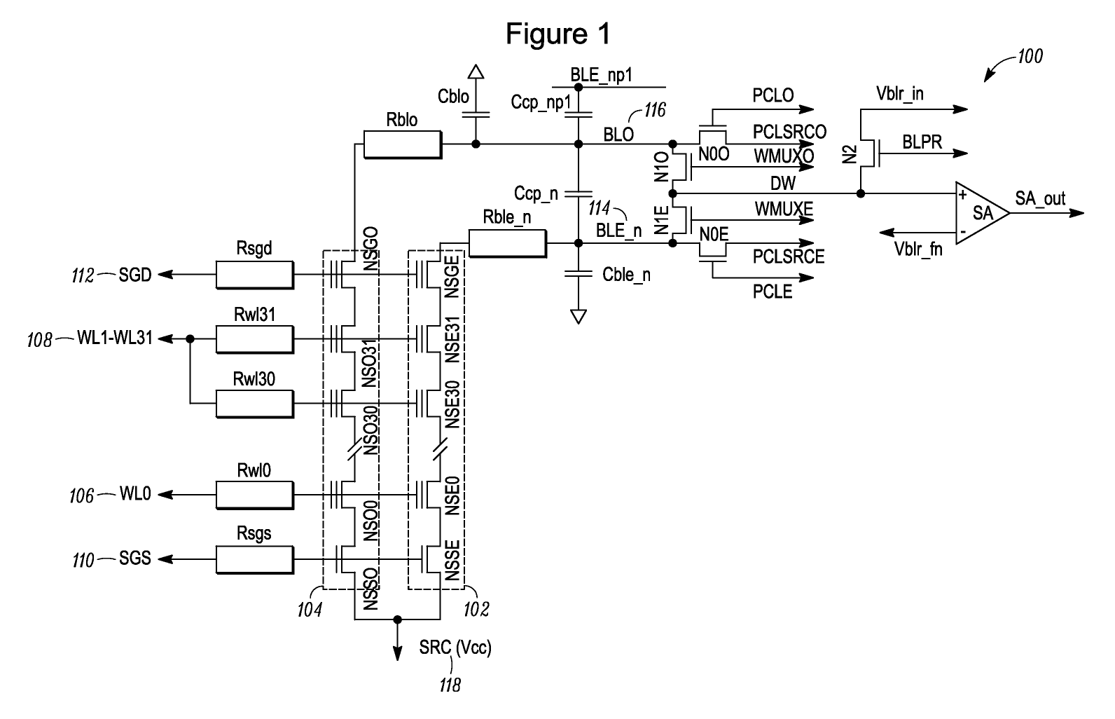

FIG. 1 is a circuit diagram of a memory device for string resistance compensation, according to but one embodiment. In an embodiment, memory device 100 comprises a first string of memory cells 102, a second string of memory cells 104, a first word line (WL0) 106, one or more second word lines (WL1-WL31) 108, a select gate source line (SGS) 110, a select gate drain line (SGD) 112, a first bit line (BLE_n) 114, a second bit line (BLO) 116, and source line (SRC) 118, coupled as shown. First string of memory cells 102 may comprise gate select device (NSSE), memory cells (NSE0-NSE30, NSE31), and gate drain device (NSGE), coupled as shown. Second string of memory cells 104, may comprise gate select device (NSSO), memory cells (NSO0-NS030, NSE31), and gate drain device (NSGO), coupled as shown. Memory device 100 may further comprise resistors (Rsgd, Rwl0-Rwl30, Rwl31, Rsgs, Rblo, Rble_n), capacitors such as coupling and/or field plate capacitors (Cblo, Cble_n, Ccp_n, Ccp_np1), initial pre-charge circuitry (N2), multiplexing circuitry (N1E, N1O, N0E, N0O), and sense amplifier (SA) circuitry, coupled as shown. Memory device 100 may comprise more or fewer bit lines 114, 116, word lines 106, 108, and/or other elements than depicted in FIG. 1 in other embodiments.

In an embodiment, first bit line BLE_n 114 of the multiplexed couple of bit lines 114, 116 on the DW node is the selected bit line and first word line WL0 106 is the selected word line, thus, making cell NSE0 the selected memory cell. In other embodiments, other memory cells may be similarly selected. First string of memory cells 102 may be referred to as the “selected string” to signify that a selected memory cell, NSE0, is within the selected string although other cells within the first string of memory cells 102 may not be selected. In this scenario, second string of memory cells 104 may be referred to as the “unselected string.”

The current of the NSE0 cell may be read by a sequence of actions. In an embodiment, the select gate source SGS 110 is biased to ground voltage, the select gate drain SGD 112 is biased to a pass voltage (Vsgd), the selected first word line WL0 106 is biased to a read voltage (Vwl_read), and the unselected second word lines WL1-WL31 108 are biased to a pass voltage (Vpass_read). Ground voltage may be a voltage that includes zero voltage or non-zero voltages. Such biasing may be followed by a pre-charge of the selected first bit line BLE_n 114 toward a constant voltage (Vblr_in). The selected first bit line BLE_n 114 may be pre-charged to an initial or start voltage (Vblr_in) by turning on pre-charge device N2 and multiplexing device N1E by applying to their gates a voltage high enough to pass the constant voltage (Vblr_in), while turning on multiplexing device N0O to connect the unselected bit line BLO 116 to the line PCLSRCO, which may be connected to ground voltage for shielding purposes.

A developing phase during which the selected first bit-line BLE_n 114 discharges may follow the initial pre-charge of the selected first bit-line BLE_n 1 14. Developing phase may be triggered by switching events including, for example, turning off pre-charge device N2 and turning on gate select device NSSE by applying to the select gate source SGS 110 a pass voltage (Vsgs). The selected first bit-line BLE_N 114 may discharge via the selected cell NSE0 through the selected first string of memory cells 102. The developing phase may occur for a fixed amount of time called developing time (T_{dev}).

Assuming, for simplicity, that the discharge current is constant, the average cell discharge current, I_{cell}_{_{—}}ₐᵥ, may be calculated according to the following relationship where C_{cp}_{_{—}}ₙ, is the capacitance of capacitor Ccp_n, C_{ble}_{_{—}}ₙ, is the capacitance of capacitor Cble_n, V_{blr}_{_{—}}ᵢₙ is the voltage of line Vblr_in, V_{BLE}_{_{—}}ₙ is the voltage that the selected first bit line BLE_n 114 will reach at the end of the developing time, ΔV_{BLE}_{_{—}}ₙ is a voltage measurement error due to pattern dependent string resistance, and T_{dev} is developing time:

I_{cell}_{_{—}}ₐᵥ=(C_{cp}_{_{—}}ₙ+C_{ble}_{_{—}}ₙ)·(V_{blr}_{_{—}}ₙ−V_{BLE}_{_{—}}ₙ−ΔV_{BLE}_{_{—}}ₙ)/T_{dev} [1]

Average cell discharge current, I_{cell}_{_{—}}ₐᵥ, may depend on the threshold voltage (Vt) of the selected cell (i.e., NSEO), but may also depend on the string resistance of the unselected cells (i.e., NSE1-NSE31) in the selected string 102 due to the cumulative resistance of the unselected cells, which may depend on the threshold voltages (Vt) of the unselected cells. ΔV_{BLE}_{_{—}}ₙ may be inversely proportional to the string resistance (R_{string}). The term ΔV_{BLE}_{_{—}}ₙ may represent a Vt measurement error to account for the dependence of the string resistance and may be considered independent of the selected cell Vt in equation [1].

In an embodiment, a memory device 100 is capable of using a sensing scheme that compensates for R_{string} dependency in the I_{cell}_{_{—}}ₐᵥ by offsetting the ΔV_{BLE}_{_{—}}ₙ. An additional compensation or offset voltage, ΔV_{pch}_{_{—}}ₛₜᵣ, may be added to the selected first bit line BLE_n 1 14. The string resistance (R_{string}) may be exploited to obtain offset value ΔV_{pch}_{_{—}}ₛₜᵣ. In this way, equation [1] becomes:

I_{cell}_{_{—}}ₐᵥ=(C_{cp}_{_{—}}ₙ+C_{ble}_{_{—}}ₙ)·(ΔV_{pch}_{_{—}}ₛₜᵣ+Vblr_{—in}−V_{BLE}_{_{—}}ₙ−ΔV_{BLE}_{_{—}}ₙ)/T_{dev} [2]

The offset value ΔV_{pch}_{_{—}}ₛₜᵣ may be applied such that the following relationship is true or closely approximated for a defined range of bias voltages applied to the selected first wordline WL0 106, unselected second wordlines WL1-WL31 108, select gate source SGS 110, and select gate drain SGD 112:

ΔVₚₕ_{_{—}}ₛₜᵣ−ΔV_{BLE}_{_{—}}ₙ=0 [3]

In this manner, pattern dependent R_{string} noise may be significantly reduced or eliminated resulting in an increased read window budget for a memory device 100.

In an embodiment, ΔV_{pch}_{_{—}}ₛₜᵣ is added to the selected first bit line BLE_n 114 voltage by using an additional pre-charge following the initial pre-charge of BLE_n 114 to a constant voltage (Vblr_in). The additional pre-charge may be referred to as a “compensation pre-charge” and may be implemented prior to the developing phase. In an embodiment, the compensation pre-charge is applied from the source line (SRC) side through the selected string while sufficient biases are applied to the selected first wordline WL0 106, unselected second wordlines WL1-WL31 108, select gate source SGS 110, and select gate drain SGD 112. The compensation pre-charge may be performed for a fixed time, T_{pch}_{_{—}}ₛₜᵣ. Equation [3] may be approximated or obtained by, for example, modulating the time, T_{pch}_{_{—}}ₛₜᵣ, or voltage biases of the select gate drain SGD 112 during the compensation pre-charge.

A variety of pre-charge sequences, associated bias voltages, and circuitry arrangements are possible within the scope of the subject matter described herein to compensate for string resistance. In one embodiment, a memory device 100 for string resistance compensation comprises a first string of memory cells 102, a first word line WL0 106 coupled with the first string of memory cells 102, one or more second word lines WL1-WL31 108 coupled with the first string of memory cells 102, a select gate source SGS line 110 coupled with the first string of memory cells 102, a select gate drain SGD line 112 coupled with the first string of memory cells 102, and a first bit line BLE_n 114 coupled with the first string of memory cells 102 wherein a memory cell (i.e., NSE0) of the first string of memory cells 102 is read, in part, by pre-charging the first bit line BLE_n 114 through the first string of memory cells 102 to compensate for resistance of unselected cells (i.e., NSE1-NSE31) in the first string of memory cells 102.

Select gate source SGS 110 may be a control signal to connect the source side of all strings 102, 104 in a single block wherein the block is an independently erasable array portion. Select gate drain SGD 112 may be a control signal to connect the drain side of the strings 102, 104 in a single block to their respective bit lines 114, 116.

Memory device 100 may further comprise a source line SRC 118 coupled with the first string of memory cells 102. Source line SRC 118 may be coupled to a source terminal of the NSSE and NSSO devices and may be common to all strings 102, 104 in the array. In an embodiment, the first bit line BLE_n 114 is pre-charged to compensate for resistance of unselected cells in the first string of memory cells 102 by applying a supply voltage (Vcc) that is greater than a previous voltage (Vblr_in) of the first bit line BLE_n 114 to the source line SRC 118 to turn on the select gate source SGS 110 and applying a bias voltage (Vsgd_pch) to the select gate drain SGD 112 to control the amount of voltage used to provide compensation pre-charge to the first bit line BLE_n 1 14. Compensation pre-charge may be applied from the source line SRC 118 side. For example, one or more transistors or gate select devices (NSSE, NSSO) may be coupled with the source line SRC 118 and the select gate source SGS 110 such that the select gate source SGS 110 is turned on by applying a voltage (Vsgs) high enough to overcome the threshold voltages of the one or more transistor or gate select devices (NSSE, NSSO).

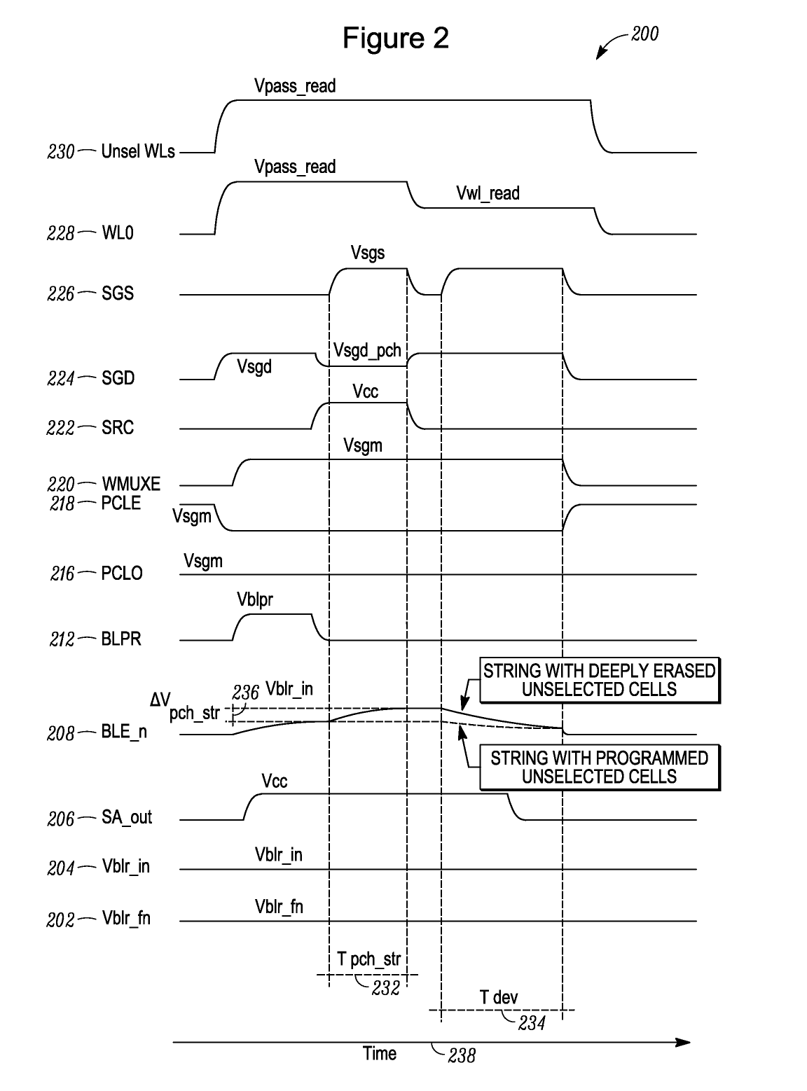

In an embodiment, memory device 100 further comprises a second string of memory cells 104 coupled with the first word line WL0 106, the one or more second word lines WL1-WL31 108, the select gate source SGS line 110, and the select gate drain SGD line 112. Memory device 100 may further comprise a second bit line BLO 116 coupled with the second string of memory cells 104 wherein the second bit line BLO 116 is set to ground voltage while pre-charging the first bit line BLE_n 114 to compensate for resistance of unselected cells in the first string of memory cells 102. Such embodiment may be further described with respect to FIG. 2.

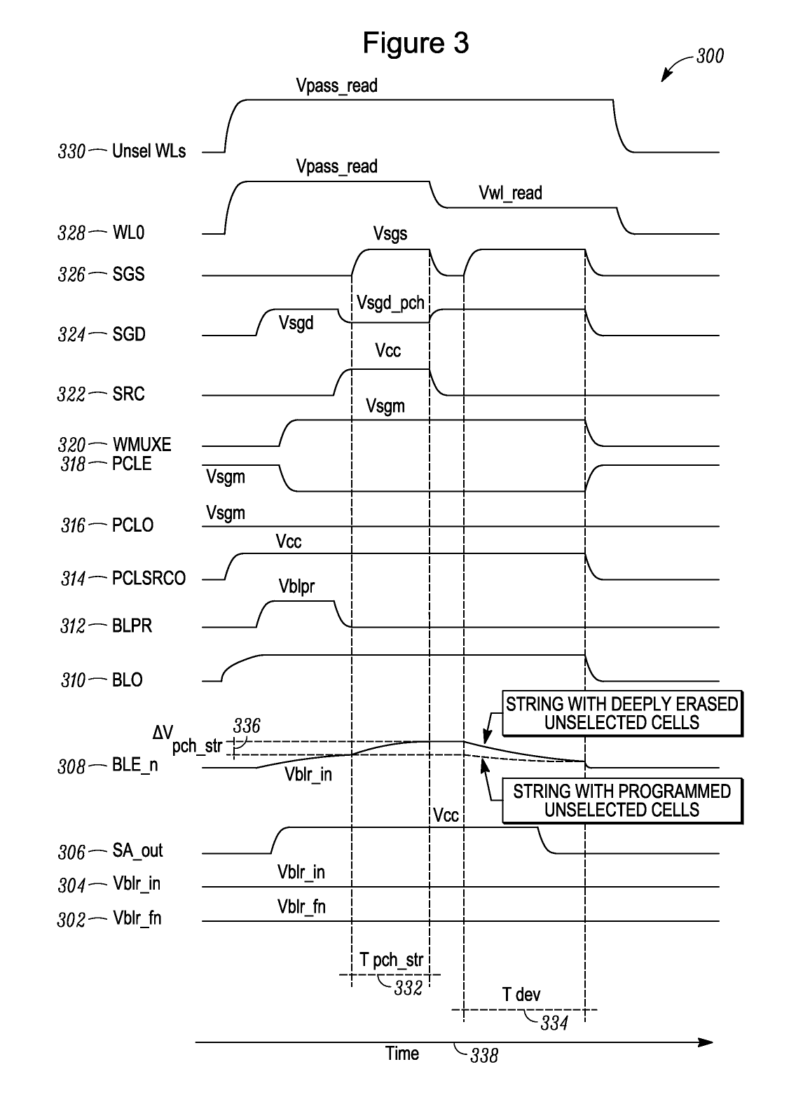

In another embodiment, memory device 100 further comprises a second bit line BLO 116 coupled with the second string of memory cells 102 wherein the second bit line BLO 116 is pre-charged to a supply voltage (Vcc) to prevent current from flowing in the second string of memory cells 104 while pre-charging the first bit line BLE_n 114 to compensate for resistance of unselected cells in the first the string of memory cells 102. Such embodiment may be further described with respect to FIG. 3.

Memory device 100 may further comprise multiplexing circuitry comprising one or more transistors (N1E, N1O, N0E, N0O) coupled with the first bit line BLE_n 114. Sense amplifier (SA) circuitry may be coupled with the multiplexing circuitry. In one embodiment, sense amplifier serves as a voltage comparator.

Memory device 100 may comprise any suitable memory that comprises string array structures or is read by measuring current of the selected memory cell, or combinations thereof, including, for example, flash memory, DRAM, or other types of memory. In an embodiment, the first string of memory cells 102 comprises an element of a NAND flash memory device. In another embodiment, pre-charging the first bit line (BLE_n) through the first string of memory cells 102 to compensate for resistance of unselected cells in the first string of memory cells 102 reduces pattern-dependent noise during read operations or increases the read window of the NAND flash memory device, or combinations thereof.

FIG. 2 is a schematic of a first sequence to provide string resistance compensation in a memory device, according to but one embodiment. The first sequence 200 to provide string resistance compensation may depict an example sequence based on the memory device 100 of FIG. 1 wherein the first bit line BLE_n 114 is the selected bit line and first word line WL0 106 is the selected word line, thus making cell NSE0 the selected memory cell. In an embodiment, the first sequence 200 to provide string resistance compensation comprises voltage diagrams for a variety of signal pathways of memory device 100 including, for example, Vblr_fn 202, Vblr_in 204, SA_out 206, selected bit line BLE_n 208, BLPR 212, PCLO 216, PCLE 218, WMUXE 220, source line SRC 222, select gate device SGD 224, select gate source 226, selected word line WL0 228, and unselected word lines WL1-WL31 230. Signal pathways of memory device 100 that are not depicted in first sequence 200 may have a voltage of 0 V or a voltage to turn the signal pathways or transistors off, or combinations thereof. In an embodiment, first sequence 200 further depicts the passage of time as represented by arrow 238 in the direction of the arrow, compensation pre-charge time, T_{pch}_{_{—}}ₛₜᵣ, 232, developing time, T_{dev}, 234, and compensation pre-charge offset voltage ΔV_{pch}_{_{—}}ₛₜᵣ 236.

In an embodiment, a first sequence 200 to provide string resistance compensation in a memory device comprises applying voltages to a selected word line WL0 228, one or more unselected word lines WL1-WL31 230, select gate source SGS 226, and select gate drain SGD 228 prior to pre-charging a selected bit line BLE_n 208. Selected word line WL0 228, one or more unselected word lines WL1-WL31 230, select gate source SGS 226, and select gate drain SGD 228 may be coupled with a selected string of memory cells. Applying voltages to a selected word line WL0 228, one or more unselected word lines WL1-WL31 230, select gate source SGS 226, and select gate drain SGD 228 may comprise setting the select gate source SGS 226 to ground voltage, setting the select gate drain SGD 224 to a first pass voltage (Vsgd), and setting the selected word line WL0 228 and the one or more unselected word lines WL1-WL31 230 to a second pass voltage (Vpass_read) that is higher than the highest threshold voltage (Vt) of the cells of the selected string of memory cells. Second pass voltage (Vpass_read) may be higher than voltage Vwl_read to make the compensation pre-charge of selected bit line BLE_n 208 primarily dependent on the string resistance and not on the selected cell threshold voltage (Vt).

First sequence 200 may further comprise pre-charging a selected bit line BLE_n 208 toward a constant voltage (Vblr_in) after applying voltages as described above to selected word line WL0 228, one or more unselected word lines WL1-WL31 230, select gate source SGS 226, and select gate drain SGD 228. The selected bit line BLE_n 208 may be coupled with the selected string of memory cells. Pre-charging a selected bit line BLE_n 208 toward a constant voltage (Vblr_in) may be accomplished by, for example, turning on one or more transistors (i.e., N2 and N1E) coupled with the selected bit line BLE_n 208 by applying a voltage high enough to pass the constant voltage (Vblr_in) of the selected bit line BLE_n 208 to the gates of the one or more transistors and turning on another transistor (i.e., N0O) to set an unselected bit line (BLO) to ground voltage (i.e., through PCLSRCO).

In an embodiment, first sequence 200 further comprises pre-charging a selected bit line BLE_n 208 through the selected string of memory cells to compensate for resistance of unselected cells in the selected string of memory cells. Pre-charging the selected bit line BLE_n 208 to compensate for resistance of unselected cells in the selected string of memory cells may comprise setting a source line SRC 222 coupled with the selected string of memory cells to a supply voltage (Vcc) to turn on the select gate source SGS 226. In an embodiment, the supply voltage (Vcc) is greater than the constant voltage (Vblr_in) applied to initially pre-charge the selected bit line. Select gate source SGS 226 may be turned on with a voltage (Vsgs) high enough to overcome the threshold voltages of one or more transistors or select gate devices (i.e., NSSE and NSSO) coupled with the select gate source SGS 226. In an embodiment, compensation pre-charge of selected bit line BLE_n 208 further comprises applying a bias voltage (Vsgd_pch) to the select gate drain SD 224 to control the amount of voltage used to pre-charge the selected bit line BLE_n 208 through the selected string of memory cells.

Compensation pre-charge of selected bit line BLE_n 208 may occur for a time interval, T_{pch}_{_{—}}ₛₜᵣ 232, delimited by the first rising and falling edge of voltage Vsgs of select gate source SGS 226 as depicted. The voltage offset, ΔV_{pch}_{_{—}}ₛₜᵣ 236, described with respect to FIG. 1 may be added to the voltage of the selected bit line BLE_n 208 by applying the compensation pre-charge. The voltage pathway of selected bit line BLE_n 208 includes a voltage pathway for a selected string with deeply erased unselected cells and a dashed voltage pathway for a selected string with programmed unselected cells as labeled in FIG. 2.

First sequence 200 may further comprise discharging the selected bit line BLE_n 208 after the compensation pre-charge. Discharging may occur during a development phase for a developing time interval, T_{dev} 234, delimited by the second rising and falling edge of voltage Vsgs of select gate source SGS 226. Developing phase may be triggered by applying a pass voltage (Vsgs) to the select gate source SGS 226 to turn on a select gate device (i.e., NSSE) coupled with the select gate source. In an embodiment, sequence 200 comprises discharging the selected bit line BLE_n 208 through the selected string of memory cells. The selected word line WL0 228 may be biased to a voltage (Vwl_read) that is higher than the threshold voltage (Vt) of the selected cell of the selected string of memory cells.

First sequence 200 may depict an embodiment wherein an unselected bit line BLO is set to ground voltage while pre-charging the selected bit line BLE_n 208 toward a constant voltage (Vblr_in) and while pre-charging the selected bit line BLE_n 208 through the selected string of memory cells to compensate for resistance of unselected cells in the selected string of memory cells. The unselected bit line BLO may have other applied voltages in other embodiments as described with respect to FIG. 3.

FIG. 3 is a schematic of a second sequence to provide string resistance compensation in a memory device, according to but one embodiment. The second sequence 300 to provide string resistance compensation may also depict an example sequence based on the memory device 100 of FIG. 1 wherein the first bit line BLE_n 114 is the selected bit line and first word line WL0 106 is the selected word line, thus making cell NSE0 the selected memory cell. In an embodiment, the second sequence 300 to provide string resistance compensation comprises voltage diagrams for a variety of signal pathways of memory device 100 including, for example, Vblr_fn 302, Vblr_in 304, SA_out 306, selected bit line BLE_n 308, unselected bit line BLO 310, BLPR 312, PCLSRCO 314, PCLO 316, PCLE 318, WMUXE 320, source line SRC 322, select gate device SGD 324, select gate source 326, selected first word line WL0 328, and unselected word lines WL1-WL31 330. Signal pathways of memory device 100 that are not depicted in second sequence 300 may have a voltage of 0 V or a voltage to turn the signal pathways or transistors off, or combinations thereof. In an embodiment, second sequence 300 further depicts the passage of time as represented by arrow 338 in the direction of the arrow, compensation pre-charge time, T_{pch}_{_{—}}ₛₜᵣ, 332, developing time, T_{dev}, 334, and compensation pre-charge offset voltage ΔV_{pch}_{_{—}}ₛₜᵣ 336.

Second sequence 300 may be similar to first sequence 200 except the second sequence 300 may further comprise pre-charging an unselected bit line BLO 310 to a supply voltage (Vcc) while the selected bit line BLE_n 308 is set to ground voltage prior to pre-charging the selected bit line BLE_n 308 toward a constant value (Vblr_in). In an embodiment, such biasing of unselected bit line BLO 310 prevents current from flowing in an unselected string of memory cells (i.e., NSSO, NSO0-NSO31, NSGO) while pre-charging the selected bit line BLE_n 308 through the selected string of memory cells to compensate for resistance of unselected cells in the selected string of memory cells. In an embodiment, the unselected bit line BLO 310 is pre-charged to a supply voltage (Vcc) through device N0O.

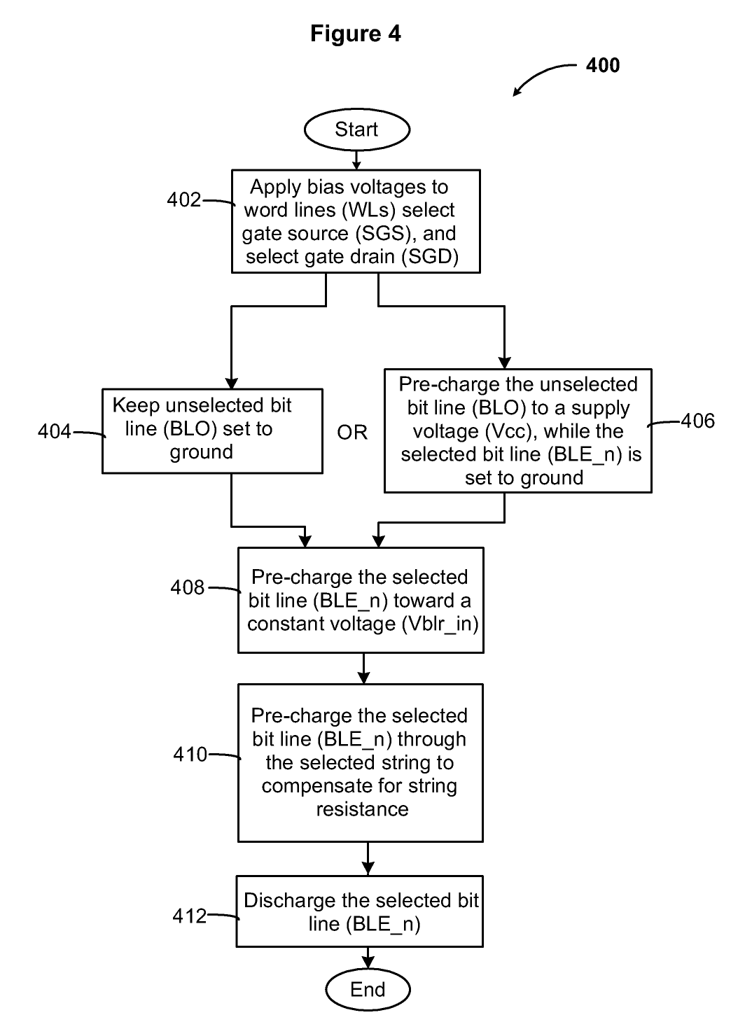

FIG. 4 is a flow diagram of a method to provide string resistance compensation in a memory device, according to but one embodiment. In an embodiment, method 400 includes applying bias voltages to wordlines, select gate source SGS, and select gate drain SGD at box 402, keeping unselected bit line BLO set to ground at box 404 or, alternatively, pre-charging the unselected bit line BLO to a supply voltage (Vcc) while the selected bit line BLE_n is set to ground at box 406, pre-charging the selected bit line BLE_n toward a constant voltage (Vblr_in) at box 408, pre-charging the selected bit line BLE_n through the selected string to compensate for string resistance at box 410, and discharging the selected bit line BLE_n at box 412. Pre-charging the unselected bit line BLO to a supply voltage (Vcc) while the selected bit line BLE_n is set to ground at box 406 may be used to prevent current from flowing through the unselected string while pre-charging the selected bit line BLE_n 408, 410.

Method 400 may comprise applying voltages to a selected word line WL0, one or more unselected word lines WL1-WL31, a select gate source SGS, and a select gate drain SGD 402 wherein the selected word line WL0, the one or more unselected word lines WL1-WL31, the select gate source SGS, and the select gate drain SGD are coupled with a selected string of memory cells. In an embodiment, applying voltages to the selected word line WL0, the one or more unselected word lines WL1-WL31, the select gate source SGS, and the select gate drain SGD 402 comprises setting the select gate source SGS to ground voltage, setting the select gate drain SGD to a first pass voltage (Vsgd) and setting the selected word line WL0 and the one or more unselected word lines WL1-WL31 to a second pass voltage (Vpass_read) that is higher than the highest threshold voltage (Vt) of the cells of the selected string of memory cells.

In an embodiment, method 400 further comprises pre-charging a selected bit line BLE_n toward a constant voltage (Vblr_in) 408 wherein the selected bit line BLE_n is coupled with the selected string of memory cells. Pre-charging a selected bit line BLE_n toward a constant voltage (Vblr_in) 408 may comprise turning on one or more transistors (i.e., N2 and N1E) coupled with the selected bit line BLE_n by applying a voltage high enough to pass the constant voltage (Vblr_in) of the selected bit line BLE_n to the gates of the one or more transistors and turning on another transistor (i.e., N0O) to set an unselected bit line BLO to ground voltage (i.e., through PCLSRCO 404.

In an embodiment, unselected bit line BLO is kept at ground voltage 404 while pre-charging the selected bit line BLE_n 408, 410. In an alternative embodiment, method 400 comprises pre-charging an unselected bit line BLO to a supply voltage (Vcc) while the selected bit line BLE_n is initially set to ground voltage 406 prior to pre-charging the selected bit line BLE_n toward a constant value (Vblr_in). Such biasing of unselected bit line BLO to the supply voltage (Vcc) 406 may be maintained to prevent current from flowing in an unselected string of memory cells while pre-charging the selected bit line BLE_n to compensate for resistance of unselected cells in the selected string of memory cells 410.

Method 400 may further comprise pre-charging the selected bit line BLE_n through the selected string of memory cells to compensate for resistance of unselected cells in the selected string of memory cells 410. In an embodiment, pre-charging the selected bit line BLE_n to compensate for string resistance 410 comprises setting a source line SRC coupled with the selected string of memory cells to a supply voltage (Vcc) to turn on the select gate source SGS wherein the supply voltage (Vcc) is greater than the constant voltage (Vblr_in) and applying a bias voltage (Vsgd_pch) to the select gate drain SGD to control the amount of voltage used to pre-charge the selected bit line BLE_n through the selected string of memory cells.

In an embodiment, method 400 further comprises discharging the selected bit line BLE_n 412. The selected bit line BLE_n may be discharged 412 through the selected string of memory cells wherein the selected word line WL0 is biased to a voltage (Vwl_read) that is higher than the threshold voltage (Vt) of the selected cell of the selected string of memory cells.

String resistance compensation may be achieved by pre-charging the selected bit line (BLE_n) through the selected string to compensate for string resistance 410. The voltage offset, ΔV_{pch}_{_{—}}ₛₜᵣ, described with respect to FIG. 1 may be added to the voltage of the selected bit line BLE_n by applying the compensation pre-charge.

Method 400 may include embodiments already described with respect to FIGS. 1-3. Various operations may be described as multiple discrete operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

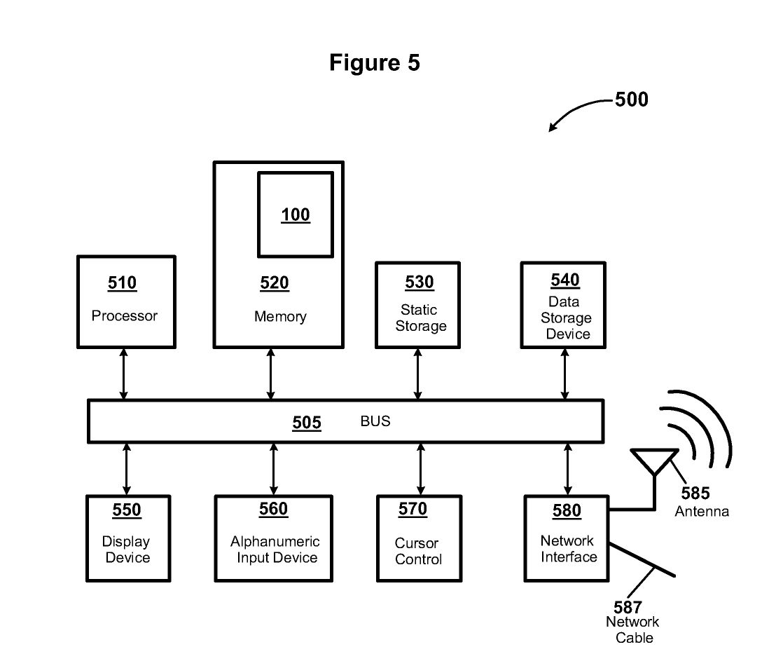

FIG. 5 is a diagram of an example system in which a memory device as described herein may be used, according to but one embodiment. System 500 is intended to represent a range of electronic systems (either wired or wireless) including, for example, desktop computer systems, laptop computer systems, personal computer (PC), wireless telephones, personal digital assistants (PDA) including cellular-enabled PDAs, set top boxes, pocket PCs, tablet PCs, DVD players, or servers, but is not limited to these examples and may include other electronic systems. Alternative electronic systems may include more, fewer and/or different components.

Electronic system 500 may include bus 505 or other communication device to communicate information, and processor 510 coupled to bus 505 that may process information. While electronic system 500 is illustrated with a single processor, system 500 may include multiple processors and/or co-processors. System 500 may also include random access memory (RAM) or other storage device 520 (referred to as memory), coupled to bus 505 and may store information and instructions that may be executed by processor 510.

Memory 520 may also be used to store temporary variables or other intermediate information during execution of instructions by processor 510. In one embodiment, memory 520 includes a memory device 100 for string resistance compensation as described herein. Memory 520 is a flash memory device in one embodiment.

System 500 may also include read only memory (ROM) and/or other static storage device 530 coupled to bus 505 that may store static information and instructions for processor 510. Data storage device 540 may be coupled to bus 505 to store information and instructions. Data storage device 540 such as a magnetic disk or optical disc and corresponding drive may be coupled with electronic system 500.

Electronic system 500 may also be coupled via bus 505 to display device 550, such as a cathode ray tube (CRT) or liquid crystal display (LCD), to display information to a user. Alphanumeric input device 560, including alphanumeric and other keys, may be coupled to bus 505 to communicate information and command selections to processor 510. Another type of user input device is cursor control 570, such as a mouse, a trackball, or cursor direction keys to communicate information and command selections to processor 510 and to control cursor movement on display 550.

Electronic system 500 further may include one or more network interfaces 580 to provide access to network, such as a local area network. Network interface 580 may include, for example, a wireless network interface having antenna 585, which may represent one or more antennae. Network interface 580 may also include, for example, a wired network interface to communicate with remote devices via network cable 587, which may be, for example, an Ethernet cable, a coaxial cable, a fiber optic cable, a serial cable, or a parallel cable.

In one embodiment, network interface 580 may provide access to a local area network, for example, by conforming to an Institute of Electrical and Electronics Engineers (IEEE) standard such as IEEE 802.11b and/or IEEE 802.11g standards, and/or the wireless network interface may provide access to a personal area network, for example, by conforming to Bluetooth standards. Other wireless network interfaces and/or protocols can also be supported.

IEEE 802.11b corresponds to IEEE Std. 802.11b-1999 entitled “Local and Metropolitan Area Networks, Part 11: Wireless LAN Medium Access Control (MAC) and Physical Layer (PHY) Specifications: Higher-Speed Physical Layer Extension in the 2.4 GHz Band,” approved Sep. 16, 1999 as well as related documents. IEEE 802.11g corresponds to IEEE Std. 802.11g-2003 entitled “Local and Metropolitan Area Networks, Part 11: Wireless LAN Medium Access Control (MAC) and Physical Layer (PHY) Specifications, Amendment 4: Further Higher Rate Extension in the 2.4 GHz Band,” approved Jun. 27, 2003 as well as related documents. Bluetooth protocols are described in “Specification of the Bluetooth System: Core, Version 1.1,” published Feb. 22, 2001 by the Bluetooth Special Interest Group, Inc. Previous or subsequent versions of the Bluetooth standard may also be supported.

In addition to, or instead of, communication via wireless LAN standards, network interface(s) 580 may provide wireless communications using, for example, Time Division, Multiple Access (TDMA) protocols, Global System for Mobile Communications (GSM) protocols, Code Division, Multiple Access (CDMA) protocols, and/or any other type of wireless communications protocol.

In an embodiment, a system 500 includes one or more omnidirectional antennae 585, which may refer to an antenna that is at least partially omnidirectional and/or substantially omnidirectional, a processor 510 coupled to communicate via the antennae, and memory 520 or a memory device 100 as described herein coupled with the processor. According to various embodiments, memory device 520 accords with embodiments described with respect to FIGS. 1-4.

The above description of illustrated embodiments, including what is described in the Abstract, is not intended to be exhaustive or to limit to the precise forms disclosed. While specific embodiments and examples are described herein for illustrative purposes, various equivalent modifications are possible within the scope of the description, as those skilled in the relevant art will recognize.

These modifications can be made in light of the above detailed description. The terms used in the following claims should not be construed to limit the scope to the specific embodiments disclosed in the specification and the claims. Rather, the scope of the embodiments disclosed herein is to be determined by the following claims, which are to be construed in accordance with established doctrines of claim interpretation.

What is claimed is:

1. An apparatus comprising:
a first string of memory cells; and
a first bit line coupled with the first string of memory cells wherein a memory cell of the first string of memory cells is read, in part, by pre-charging the first bit line through the first string of memory cells to compensate for resistance of unselected cells in the first string of memory cells.

2. An apparatus according to claim 1 further comprising:
a source line coupled with the first string of memory cells wherein the first bit line is pre-charged to compensate for resistance of unselected cells in the first string of memory cells by applying a supply voltage that is greater than a previous voltage of the first bit line to the source line to turn on a select gate source coupled with the first string of memory cells and applying a bias voltage to a select gate drain coupled with the first string of memory cells to control the amount of voltage used to pre-charge the first bit line.

3. An apparatus according to claim 2 further comprising:
one or more transistors coupled with the source line and the select gate source wherein the select gate source is turned on by applying a voltage high enough to overcome threshold voltages of the one or more transistors.

4. An apparatus according to claim 1 further comprising:
a first word line coupled with the first string of memory cells;
one or more second word lines coupled with the first string of memory cells;
a select gate source line coupled with the first string of memory cells; and
a select gate drain line coupled with the first string of memory cells.

5. An apparatus according to claim 4 further comprising:
a second string of memory cells coupled with the first word line, the one or more second word lines, the select gate source line, and the select gate drain line; and
a second bit line coupled with the second string of memory cells wherein the second bit line is set to ground voltage while pre-charging the first bit line to compensate for resistance of unselected cells in the first string of memory cells.

6. An apparatus according to claim 4 further comprising:
a second string of memory cells coupled with the first word line, the one or more second word lines, the select gate source line, and the select gate drain line; and
a second bit line coupled with the second string of memory cells wherein the second bit line is pre-charged to a supply voltage to prevent current from flowing in the second string of memory cells while pre-charging the first bit line to compensate for resistance of unselected cells in first the string of memory cells.

7. An apparatus according to claim 1 wherein the first string of memory cells comprises an element of a NAND flash memory device and wherein pre-charging the first bit line through the first string of memory cells to compensate for resistance of unselected cells in the first string of memory cells reduces pattern-dependent noise during read operations or increases the read window of the NAND flash memory device, or combinations thereof.

8. A method comprising:
applying voltages to a selected word line, one or more unselected word lines, a select gate source, and a select gate drain wherein the selected word line, the one or more unselected word lines, the select gate source, and the select gate drain are coupled with a selected string of memory cells;
pre-charging a selected bit line toward a constant voltage wherein the selected bit line is coupled with the selected string of memory cells; and
pre-charging the selected bit line through the selected string of memory cells to compensate for resistance of unselected cells in the selected string of memory cells.

9. A method according to claim 8 wherein applying voltages to the selected word line, the one or more unselected word lines, the select gate source, and the select gate drain comprises:
setting the select gate source to ground voltage;
setting the select gate drain to a first pass voltage; and
setting the selected word line and the one or more unselected word lines to a second pass voltage that is higher than the highest threshold voltage of the cells of the selected string of memory 7 cells.

10. A method according to claim 8 wherein pre-charging the selected bit line toward the constant voltage comprises:
turning on one or more transistors coupled with the selected bit line by applying a voltage high enough to pass the constant voltage of the selected bit line to the gates of the one or more transistors; and
turning on another transistor to set an unselected bit line to ground voltage.

11. A method according to claim 8 wherein pre-charging the selected bit line through the selected string of memory cells to compensate for resistance of unselected cells in the selected string of memory cells comprises:
setting a source line coupled with the selected string of memory cells to a supply voltage to turn on the select gate source wherein the supply voltage is greater than the constant voltage; and
applying a bias voltage to the select gate drain to control the amount of voltage used to pre-charge the selected bit line through the selected string of memory cells.

12. A method according to claim 8 further comprising:
discharging the selected bit line through the selected string of memory cells wherein the selected word line is biased to a voltage that is higher than the threshold voltage of the selected cell of the selected string of memory cells.

13. A method according to claim 8 further comprising:
setting an unselected bit line to ground voltage while pre-charging the selected bit line toward a constant voltage and while pre-charging the selected bit line through the selected string of memory cells to compensate for resistance of unselected cells in the selected string of memory cells.

14. A method according to claim 8 further comprising:
pre-charging an unselected bit line to a supply voltage while the selected bit line is set to ground voltage prior to pre-charging the selected bit line toward a constant value to prevent current from flowing in an unselected string of memory cells while pre-charging the selected bit line through the selected string of memory cells to compensate for resistance of unselected cells in the selected string of memory cells.

15. A system comprising:
an antenna;
a processor coupled to communicate via the antenna; and
a memory device coupled with the processor, the memory device comprising:
a first string of memory cells; and
a first bit line coupled with the first string of memory cells wherein a memory cell of the first string of memory cells is read, in part, by pre-charging the first bit line through the first string of memory cells to compensate for resistance of unselected cells in the first string of memory cells.

16. A system according to claim 15 wherein the memory device further comprises:
a source line coupled with the first string of memory cells wherein the first bit line is pre-charged to compensate for resistance of unselected cells in the first string of memory cells by applying a supply voltage that is greater than a previous voltage of the first bit line to the source line to turn on the select gate source and applying a bias voltage to the select gate drain to control the amount of voltage used to pre-charge the first bit line.

17. A system according to claim 15 wherein the memory device further comprises:
a first word line coupled with the first string of memory cells;
one or more second word lines coupled with the first string of memory cells;
a select gate source line coupled with the first string of memory cells; and
a select gate drain line coupled with the first string of memory cells.

18. A system according to claim 17 wherein the memory device further comprises:
a second string of memory cells coupled with the first word line, the one or more second word lines, the select gate source line, and the select gate drain line; and
a second bit line coupled with the second string of memory cells wherein the second bit line is set to ground voltage while pre-charging the first bit line to compensate for resistance of unselected cells in the first string of memory cells.

19. A system according to claim 17 wherein the memory device further comprises:
a second string of memory cells coupled with the first word line, the one or more second word lines, the select gate source line, and the select gate drain line; and
a second bit line coupled with the second string of memory cells wherein the second bit line is pre-charged to a supply voltage to prevent current from flowing in the second string of memory cells while pre-charging the first bit line to compensate for resistance of unselected cells in the first string of memory cells.

20. A system according to claim 15 wherein the memory device is read by measuring current of the memory cells and wherein pre-charging the first bit line through the first string of memory cells to compensate for resistance of unselected cells in the first string of memory cells reduces pattern-dependent noise during read operations or increases the read window of the memory device, or combinations thereof.
